(19) United States
(12) Patent Application Publication
(10) Pub. No.: US 2023/0182443 A1
(43) Pub. Date: Jun. 15, 2023

(54) RESIN COMPOSITION FOR SEMICONDUCTOR PACKAGE, COPPER CLAD LAMINATE AND CIRCUIT BOARD HAVING THE SAME

(71) Applicant: LG INNOTEK CO., LTD., Seoul (KR)

(72) Inventors: Koh Eun Lee, Seoul (KR); Han Sang Kim, Seoul (KR); Min Young Hwang, Seoul (KR)

(21) Appl. No.: 18/076,544

(22) Filed: Dec. 7, 2022

(30) Foreign Application Priority Data
Dec. 13, 2021 (KR) 10-2021-0177957

(51) Int. Cl. B32B 15/09; B32B 15/20; B32B 27/20; C08L 67/00; H05K 1/03; C08K 7/14

(52) U.S. Cl. CPC B32B 15/09; B32B 15/20; B32B 27/20; C08L 67/00; H05K 1/0366; C08K 7/14; B32B 2262/101; B32B 2457/14; C08L 2205/12; B32B 2307/204; B32B 2305/55; B32B 2305/22; B32B 2307/308

(57) ABSTRACT

A resin composition for a semiconductor package according to an embodiment includes a resin composition comprising a resin and a filler provided in the resin, wherein the resin includes a soluble liquid crystal polymer resin, and wherein the filler has a negative coefficient of thermal expansion (negative CTE) and is provided in the soluble liquid crystal polymer resin.

### CROSS-REFERENCE TO RELATED APPLICATIONS

The present application claims priority under 35 U.S.C. 119 and 35 U.S.C. 365 to Korean Patent Application No. 10-2021-0177957 (filed on Dec. 13, 2021), which is hereby incorporated by reference in its entirety.

### TECHNICAL FIELD

The embodiment relates to a resin composition for a semiconductor package, a copper clad laminate, and a circuit board including the same.

### BACKGROUND

Recently, efforts are being made to develop an improved 5th generation (5G) communication system or a pre-5G communication system in order to meet the demand for wireless data traffic.

The 5G communication system uses ultra-high frequency (mm-Wave) bands (sub 6 gigabytes (6 GHz), 28 gigabytes 28 GHz, 38 gigabytes 38 GHz or higher frequencies) to achieve high data rates.

And, a circuit board for integration of beamforming, massive MIMO, and array antennas in 5G communication systems are being developed in order to alleviate the path loss of radio waves in the very high frequency band and increase the propagation distance of radio waves.

Meanwhile, a transmission loss of an electrical signal in the circuit board is proportional to a dielectric constant and a frequency. Accordingly, the transmission loss of the signal may increase as the frequency increases, and accordingly, the signal strength may decrease, and thus the signal transmission reliability may be deteriorated. Therefore, it is important to use an insulating material having a low dielectric constant in order to reduce signal transmission loss in the circuit board.

Specifically, when the frequency of the electrical signal increases, it is important to lower the dielectric constant of a dielectric layer applied to the circuit board in order to minimize the loss of the electrical signal. That is, it is necessary to apply an insulating layer having a low dielectric constant in order to apply a high frequency to a circuit board. However, a general prepreg-type dielectric layer is composed of resin, glass fiber, and silica particles, and accordingly, there is a limit in lowering a dielectric constant and a coefficient of thermal expansion of the dielectric layer to a specific value or less by the dielectric constant and coefficient of thermal expansion (CTE) of each of the components.

On the other hand, when the dielectric constant of the dielectric layer is lowered, a strength of the dielectric layer is lowered, and thus there is a problem in that the coefficient of thermal expansion of the dielectric layer is increased.

Accordingly, there is a need for a dielectric layer having excellent electrical properties, mechanical properties and thermal properties while being applicable to a substrate using a high frequency by lowering the dielectric constant, dielectric loss, and coefficient of thermal expansion.

### SUMMARY

### Technical Problem

The embodiment provides a resin composition for a semiconductor package having a low dielectric constant, a low dielectric loss, and a low coefficient of thermal expansion, and a flexible copper clad laminate including the same, a copper clad laminate and a circuit board for a semiconductor package.

In addition, the embodiment provides a resin composition for a semiconductor package applicable to a product using a high frequency, and a flexible copper clad laminate including the same, a copper clad laminate and a circuit board for a semiconductor package.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A resin composition for a semiconductor package according to an embodiment includes a resin composition comprising a resin and a filler provided in the resin, wherein the resin includes a soluble liquid crystal polymer resin, and wherein the filler has a negative coefficient of thermal expansion (negative CTE) and is provided in the soluble liquid crystal polymer resin

In addition, the filler has a negative coefficient of thermal expansion (negative CTE) in a thickness direction of the resin or a z-axis direction.

In addition, the soluble liquid crystal polymer resin includes an organic soluble liquid crystalline aromatic polyester.

In addition, the filler has a content in a range of 12 wt % to 50 wt %, based on a total weight of the resin composition.

In addition, the filler includes any one of boron nitride (BN), graphene, zirconium tungstate (ZrW2O8), or manganese nitride-based particles.

In addition, the filler has a size in a range of 0.3 μm to 10 μm.

In addition, the filler is a plate-shaped filler, and wherein the size of the filler is a length of the plate-shaped filler.

In addition, the resin includes the soluble liquid crystal polymer resin and a thermosetting resin, and wherein the thermosetting resin includes an amide bond group.

In addition, the thermosetting resin includes any one of 4-ethynylaniline, Terephthaloyl dichloride, Isophthaloyl dichloride, and 4,4′biphenyldicarbonyl dichloride.

In addition, the resin composition further includes a glass fiber provided in the resin.

A copper clad laminate according to an embodiment includes an insulating layer; and a metal layer disposed on at least one surface of the insulating layer; wherein the insulating layer includes a resin and a filler provided in the resin, wherein the resin includes a soluble liquid crystal polymer resin, and wherein the filler has a negative coefficient of thermal expansion (negative CTE) and is provided in the soluble liquid crystal polymer resin.

In addition, the filler has a negative coefficient of thermal expansion (negative CTE) in a thickness direction of the resin or a z-axis direction.

In addition, the soluble liquid crystal polymer resin includes an organic soluble liquid crystalline aromatic polyester, and wherein the filler includes any one of boron nitride (BN), graphene, zirconium tungstate (ZrW2O8), or manganese nitride-based particles.

In addition, the filler has a content in a range of 12 wt % to 50 wt %, based on a total weight of a resin composition of the insulating layer.

In addition, the filler is a plate-shaped filler, and wherein a length of the plate-shaped filler has a range of 0.3 μm to 10 μm.

In addition, the insulating layer has a dielectric constant (Dk) in a range of 2.5 to 3.1 and a coefficient of thermal expansion (CTE) in a range of 50 ppm/K to 100 ppm/K.

In addition, the insulating layer includes a glass fiber provided in the resin.

A circuit board according to an embodiment includes an insulating layer; and a circuit pattern layer disposed on the insulating layer; wherein the insulating layer includes: a resin including a soluble liquid crystal polymer resin; and a filler provided in the resin and having a negative coefficient of thermal expansion (negative CTE), and wherein the filler has a negative coefficient of thermal expansion (negative CTE) in a thickness direction of the insulating layer.

In addition, the soluble liquid crystal polymer resin includes an organic soluble liquid crystalline aromatic polyester, wherein the filler is a plate-shaped filler including any one of boron nitride (BN), graphene, zirconium tungstate (ZrW2O8), or manganese nitride-based particles, and wherein a length of the plate-shaped filler has a range of 0.3 μm to 10 μm.

In addition, the insulating layer has a dielectric constant (Dk) in a range of 2.5 to 3.1 and a coefficient of thermal expansion (CTE) in a range of 50 ppm/K to 100 ppm/K.

### Advantageous Effects

The embodiment provides a resin composition for a semiconductor package. In this case, the resin composition for a semiconductor package includes a resin and a filler dispersed in the resin. In this case, the resin of the embodiment includes a soluble liquid crystal polymer resin (Soluble LCP). Preferably, the resin comprises organo-soluble Liquid Crystalline aromatic polyesters. In addition, the filler disposed in the resin of the embodiment has a negative coefficient of thermal expansion (negative CTE). Preferably, the filler disposed in the resin may have a negative coefficient of thermal expansion (negative CTE) in a thickness direction of an insulating layer.

Accordingly, the embodiment may reduce a dielectric constant (Dk) and a dielectric loss (Df) of the insulating layer by using the soluble liquid crystal polymer resin (Soluble LCP), and may reduce a coefficient of thermal expansion (CTE) of the insulating layer by using a filler having a negative coefficient of thermal expansion (CTE) in the thickness direction.

Accordingly, the embodiment may reduce the dielectric constant (Dk, preferably the dielectric constant at 10 GHz) of the insulating layer to 3.1 or less, 3.0 or less, or 2.9 or less, or 2.7 or less. Further, the embodiment may reduce the coefficient of thermal expansion (CTE) of the insulating layer to less than 100 ppm/K, or 98 ppm/K or less, or 95 ppm/K or less.

Accordingly, the embodiment may minimize the signal loss in a high frequency band, and furthermore, it is possible to provide an insulating layer capable of slimming while improving mechanical properties, electrical properties, and thermal properties, and a circuit board including the same.

### BRIEF DESCRIPTION OF THE DRAWINGS

FIG. 1 is a view showing a dielectric layer according to a first embodiment.

FIG. 2 is a view showing a dielectric layer according to a second embodiment.

FIG. 3 is a view showing a flexible copper clad laminate according to an embodiment.

FIG. 4 is a view showing a dielectric layer according to a third embodiment.

FIG. 5 is a view showing a copper clad laminate according to an embodiment.

FIG. 6 is a view showing a circuit board for a semiconductor package according to an embodiment.

### DETAILED DESCRIPTION OF THE EMBODIMENTS

Hereinafter, embodiments of the present disclosure will be described in detail with reference to the accompanying drawings. However, the spirit and scope of the present disclosure is not limited to a part of the embodiments described, and may be implemented in various other forms, and within the spirit and scope of the present disclosure, one or more of the elements of the embodiments may be selectively combined and replaced.

In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art. In addition, the terms used in the embodiments of the present disclosure are for describing the embodiments and are not intended to limit the present disclosure.

In this specification, the singular forms may also include the plural forms unless specifically stated in the phrase, and may include at least one of all combinations that may be combined in A, B, and C when described in “at least one (or more) of A (and), B, and C”. Further, in describing the elements of the embodiments of the present disclosure, the terms such as first, second, A, B, (a), and (b) may be used.

These terms are only used to distinguish the elements from other elements, and the terms are not limited to the essence, order, or order of the elements. In addition, when an element is described as being “connected”, “coupled”, or “connected” to another element, it may include not only when the element is directly “connected” to, “coupled” to, or “connected” to other elements, but also when the element is “connected”, “coupled”, or “connected” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements. Further, when expressed as “on (over)” or “under (below)”, it may include not only the upper direction but also the lower direction based on one element.

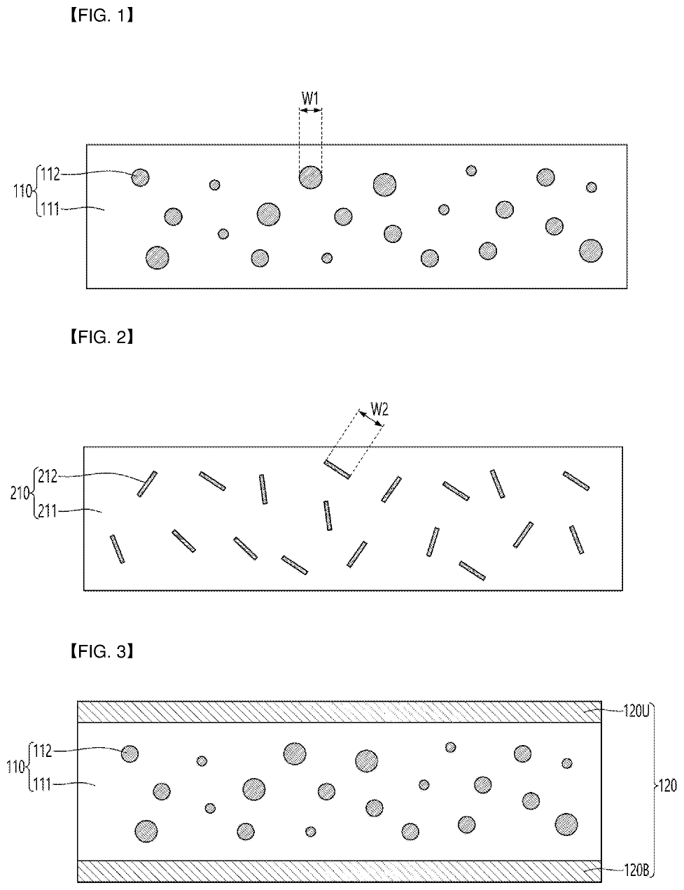

FIG. 1 is a view showing a dielectric layer according to a first embodiment, FIG. 2 is a view showing a dielectric layer according to a second embodiment, and FIG. 3 is a view showing a flexible copper clad laminate according to an embodiment.

A dielectric layer in FIGS. 1 to 3 may mean an insulating layer applied to a flexible copper clad laminate (FCCL).

For example, FIGS. 1 and 2 may show a dielectric layer or an insulating layer applied to a flexible copper clad laminate. For example, the embodiment may allow manufacturing a flexible copper clad laminate by laminating a metal layer (eg, a copper foil layer) on at least one surface of a dielectric layer or an insulating layer shown in FIGS. 1 and 2.

Hereinafter, a configuration made of a resin composition for a semiconductor package shown in FIG. 1 or FIG. 2 will be described as an insulating layer.

Referring to FIG. 1, an insulating layer 110 of the embodiment includes a resin 111 and a filler 112 dispersedly disposed in the resin 111. In the embodiment, a dielectric constant (Dk, preferably, a dielectric constant at 10 GHz) of the insulating layer 110 can be reduced to 3.1 or less by changing a composition in the insulating layer 110 constituting the resin for the semiconductor package. Preferably, the embodiment may reduce the dielectric constant Dk of the insulating layer 110 to 3.0 or less, or 2.9 or less, or 2.7 or less. Furthermore, the embodiment may reduce a dielectric loss (Df) of the insulating layer 110 to 3.0 or less, 2.9 or less, or 2.7 or less by changing a composition in the insulating layer 110. Furthermore, the embodiment may allow a coefficient of thermal expansion (CTE) of the insulating layer 110 to be reduces to less than 100 ppm/K, or 98 ppm/K or less, or 95 ppm/K or less by changing a composition in the insulating layer 110.

Preferably, the insulating layer 110 in the embodiment may have a dielectric constant (Dk) in a range of 2.5 to 3.1. Preferably, the insulating layer 110 in the embodiment may have a coefficient of thermal expansion (CTE) in a range of 50 ppm/K to 100 ppm/K.

To this end, a resin 111 included in the insulating layer 110 in the embodiment may include a thermoplastic resin. Preferably, the resin 111 may include a liquid crystal polymer (LCP).

The embodiment provides the resin 111 of the insulating layer 110 using a liquid crystal polymer resin, and accordingly, workability and adhesiveness of the insulating layer 110 may be improved, and further, mechanical properties of the insulating layer 110 may be improved.

Furthermore, the embodiment may use a liquid crystal polymer resin as the resin 111 of the insulating layer 110, and accordingly, a dielectric constant (Dk) and a dielectric loss (Df) of the insulating layer 110 can be reduced, thereby improving the electrical characteristics of the insulating layer 110.

The liquid crystal polymer resin used as the resin 111 of the insulating layer 110 may be SCLCP (Side Chain Liquid Crystal Polymers). For example, the liquid crystal polymer resin used as the resin 111 of the insulating layer 110 may be SCLCP of at least one of polyester, polyurethane, polyamide, acrylic acid, and polysiloxane.

Alternatively, the liquid crystal polymer resin used as the resin 111 of the insulating layer 110 may include MCLCP (Main-Chain Liquid Crystal Polysiloxane) or an atom group liquid crystal polymer resin. For example, the liquid crystal polymer resin used as the resin 111 of the insulating layer 110 may include at least one material having a chemical structure as shown in Table 1 below.

TABLE 1

| Kind | chemical structure |
|---|---|
| Acetylene | —C≡C—H |
| Bisacetylenes | 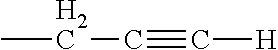 |
| Phenyl Ethynyl | 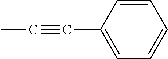 |
| Bispropargyl | —O—C≡N |
| Bismaleimides | 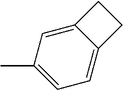 |
| Bisnadmides | 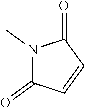 |
| Bisnadimides | 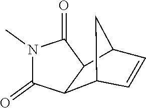 |

Alternatively, the liquid crystal polymer resin used as the resin 111 of the insulating layer 110 may be a composite liquid crystal polymer resin. For example, the liquid crystal polymer resin used as the resin 111 of the insulating layer 110 may be composed of a combination of at least two or more of MCLCP, SCLCP, and atomic group liquid crystal polymer.

The liquid crystal polymer resin has high strength at high temperature, and thus has a low coefficient of thermal expansion. In addition, the liquid crystal polymer resin has high chemical resistance, and has low dielectric constant and moisture absorption. Accordingly, the liquid crystal polymer resin has a small dimensional change due to absorption, thereby improving dimensional stability of a circuit pattern layer of the circuit board. Furthermore, the liquid crystal polymer resin has excellent corrosion resistance.

Accordingly, the embodiment can provide the insulating layer 110 with improved electrical properties, mechanical properties, and thermal properties by providing the resin 111 of the insulating layer 110 using the liquid crystal polymer resin as described above.

On the other hand, a general liquid crystal polymer resin have low processability and adhesion. Therefore, when the insulating layer 110 of the embodiment is provided by applying a liquid crystal polymer resin in the form of a general film, the insulating layer having a target dielectric constant (Dk), a target dielectric loss (Df) and a target coefficient of thermal expansion (CTE) in the embodiment (110) may not be provided.

In addition, when the insulating layer 110 is composed only of the resin 111 including the liquid crystal polymer resin, it has a high coefficient of thermal expansion (CTE). Accordingly, it is preferable that a material for improving strength is filled in the resin 111 in order to improve a physical property of the resin 111. At this time, when the resin 111 of the insulating layer 110 includes a general liquid crystal polymer resin in the form of a film, a dispersibility of the material to be filled is reduced, and thus the mechanical properties and thermal properties of the insulating layer 110 may be deteriorated.

Accordingly, the embodiment allows the resin 111 of the insulating layer 110 to be formed using a soluble liquid crystal polymer resin (Soluble LCP) without using a liquid crystal polymer resin in the form of a film.

When the resin 111 of the insulating layer 110 includes a soluble liquid crystal polymer resin (Soluble LCP), the dielectric constant (Dk), dielectric loss (Df) and coefficient of thermal expansion (CTE) of the insulating layer 110 including the liquid crystal polymer resin can be adjusted to a target level as described above, and furthermore, the dispersibility of the filler 112 filled in the insulating layer 110 may be improved.

To this end, the embodiment allows the resin used as the resin 111 of the insulating layer 110 to be composed of polyester. Preferably, the embodiment uses liquid crystalline aromatic polyesters (LCPs) as the resin 111 of the insulating layer 110. More preferably, organic soluble liquid crystalline aromatic polyesters are used as the resin 111 of the insulating layer 110 in the embodiment.

Through this, the embodiment may improve the dispersibility of the filler 112 disposed in the resin 111 of the insulating layer 110 while adjusting the dielectric constant (Dk), the dielectric loss (Df) and the coefficient of thermal expansion (CTE) of the insulating layer 110 to the target level.

Meanwhile, the insulating layer 110 includes fillers 112 dispersedly disposed in the resin 111.

The filler 112 is dispersed in the resin 111 and may be filled with a predetermined content. At this time, when the content of the filler 112 is increased, the coefficient of thermal expansion (CTE) of the insulating layer 110 may be decreased, but the dielectric constant (Dk) or the dielectric loss (Df) may be increased. Conversely, when the content of the filler 112 is decreased, the dielectric constant Dk or the dielectric loss Df of the insulating layer 110 may be decreased, but the coefficient of thermal expansion (CTE) may be increased. Accordingly, the embodiment adjusts at least one condition among a content of the filler 112, characteristics of the filler 112, and an average size of the filler 112, and accordingly, the insulating layer 110 may be have a target level of dielectric constant (Dk), dielectric loss (Df), and coefficient of thermal expansion (CTE).

In this case, the embodiment uses the filler 112 having a negative coefficient of thermal expansion (negative CTE) as the filler 112 dispersed in the resin 111 of the insulating layer 110.

Specifically, when liquid crystalline aromatic polyesters (LCPs) are used as the resin 111 of the insulating layer 110, the dielectric constant Dk of the insulating layer 110 may decrease, but the coefficient of thermal expansion (CTE) will increase. Accordingly, the filler 112 in the embodiment is dispersedly disposed in the resin 111 of the insulating layer 110 to prevent an increase in the coefficient of thermal expansion (CTE). Preferably, the filler 112 having a negative coefficient of thermal expansion (negative CTE) is dispersedly disposed in the resin 111 of the insulating layer 110. Through this, the dielectric constant Dk and the dielectric loss Df of the insulating layer 110 can be adjusted to target levels while preventing an increase in the coefficient of thermal expansion (CTE) of the insulating layer 110.

The filler 112 may include any one of boron nitride (BN), graphene, zirconium tungstate (ZrW2O8), or manganese nitride-based particles having a negative coefficient of thermal expansion (negative CTE).

In an embodiment, the insulating layer 110 may be manufactured by dispersing any one of the fillers 112 of boron nitride (BN), graphene, zirconium tungstate (ZrW2O8), or manganese nitride-based particles having a negative coefficient of thermal expansion (negative CTE) in the resin 111 composed of soluble liquid crystal polymer resin (Soluble LCP) such as liquid crystalline aromatic polyesters (LCPs).

Table 2 below shows characteristic changes of each of a first case in which the insulating layer 110 includes only the resin 111 of the embodiment, a second case including a silica filler in the resin 111, and a third case including a filler 112 having a negative coefficient of thermal expansion (negative CTE) of the embodiment in the resin 111.

TABLE 2

| | FC | Density | Dk @1 | Df @1 | CTE |
|---|---|---|---|---|---|
| CASE | (wt %) | (g/cm³) | GHz | GHz | (ppm/K) |
| First case | 0 | 1.2 | 3.3 | 0.043 | 70 |
| Second case | 35 | 1.4 | 3.4 | 0.035 | 50 |
| Third case | 35 | 1.4 | 3.4 | 0.035 | 42 |

Referring to Table 2, it was confirmed that the embodiment can further reduce the coefficient of thermal expansion (CTE) of the insulating layer 110 compared to the first case and the second case by dispersing the filler 112 having a negative coefficient of thermal expansion (negative CTE) in the resin 111.

Accordingly, the embodiment may allow the dielectric constant (Dk), dielectric loss (Df), and coefficient of thermal expansion (CTE) of the insulating layer 110 to have target levels.

On the other hand, an expansion rate (expansion rate %) of the filler 112 having the negative coefficient of thermal expansion (negative CTE) of the embodiment is shown in Table 3 below.

TABLE 3

| | | | expansion rate (expansion rate %) of |
|---|---|---|---|
| | | Expansion rate | filler having negative coefficient of |
| | | of silica filler | thermal expansion (negative CTE) |
| −100° | C. | — | — |
| −50° | C. | 0 | 0 |
| 0° | C. | +0.004 | −0.03 |
| 50° | C. | +0.006 | −0.05 |
| 100° | C. | +0.008 | −0.07 |
| 150° | C. | +0.01 | −0.085 |
| 200° | C. | +0.015 | −0.11 |
| 250° | C. | +0.02 | −0.13 |

As shown in Table 3, it can be seen that the filler 112 having a negative coefficient of thermal expansion (negative CTE) of the embodiment has a negative expansion coefficient as the temperature increases. Accordingly, the coefficient of thermal expansion (CTE) may increase as a soluble liquid crystal polymer resin (Soluble LCP) is used as the resin 111 of the insulating layer 110, and the embodiment may compensate for the increase in the coefficient of thermal expansion by using the filler 112 having the negative coefficient of thermal expansion (CTE).

Meanwhile, the filler 112 may be disposed in the insulating layer 110 with a certain level of content. For example, the filler 112 may have a content of 12 wt % to 50 wt % of a total content of the insulating layer 110. For example, the filler 112 may have a content of 15 wt % to 45 wt % of a total content of the insulating layer 110. For example, the filler 112 may have a content of 17 wt % to 42 wt % of a total content of the insulating layer 110.

When the content of the filler 112 is less than 12 wt %, the coefficient of thermal expansion (CTE) of the insulating layer 110 increases, and accordingly, mechanical properties of the insulating layer 110 and the circuit board including the insulating layer 110 may be deteriorated. For example, when the content of the filler 112 is less than 12 wt %, it may be difficult to adjust the coefficient of thermal expansion (CTE) of the insulating layer 110 to less than 100 ppm/K. In addition, when the content of the filler 112 exceeds 50 wt %, the dielectric constant Dk or the dielectric loss Df of the insulating layer 110 may increase. For example, when the content of the filler 112 exceeds 50 wt %, it may be difficult to adjust the dielectric constant Dk of the insulating layer 110 to 3.1 or less.

Meanwhile, the filler 112 may have a size W1 in a range of 0.3 μm to 10 μm. Preferably, the filler 112 may have a size W1 in a range of 0.4 μm to 8 μm. More preferably, the filler 112 may have a size W1 in a range of 0.5 μm to 2 μm.

In this case, the filler 112 of the first embodiment may have a circular shape. In addition, the size W1 of the filler 112 may mean a diameter of the filler 112. In this case, a plurality of groups of fillers having different sizes may be disposed in the resin 111 of the insulating layer 110. For example, a first filler group having a first size and a second filler group having a second size different from the first size may be disposed in the resin 111 of the insulating layer 110. In this case, the size of the filler 112 may mean an average size of the fillers occupying a certain ratio or more in the insulating layer 110. Meanwhile, the shape of the filler 112 may not have a circular shape. In addition, when the filler 112 does not have a circular shape, a virtual circle of a minimum size including the filler 112 may be drawn, and a diameter of the drawn virtual circle may be defined as the size of the filler 112. Alternatively, when the filler 112 is not circular, the size W1 of the filler 112 may be measured by a Malvern Mastersizer 3000 particle size analysis. That is, a laser is irradiated to the filler 112 using the particle size analysis, and the size of the filler 112 may be measured according to a degree of diffraction of the irradiated laser. Specifically, when fillers 112 having various sizes are disposed in the resin 111 of the insulating layer 110, the size W1 of the filler 112 may mean an average size of the fillers 112 occupying a ratio of 50% or more.

When the size W1 of the filler 112 exceeds 10 μm, the coefficient of thermal expansion (CTE) of the insulating layer 110 may increase. Specifically, when the size W1 of the filler 112 exceeds 10 μm, a size of an aggregation group formed by aggregation of a plurality of fillers may increase. And, when the size of the aggregation group increases, the filler 112 may be concentratedly disposed in a specific region in the resin 111, and accordingly, the coefficient of thermal expansion (CTE) of the insulating layer 110 may increase.

In addition, when the size W1 of the filler 112 is less than 0.3 μm, the coefficient of thermal expansion (CTE) of the insulating layer 110 may increase. Specifically, when the size W1 of the filler 112 is less than 0.3 μm, a cohesive force between the plurality of fillers may increase, and accordingly, the size of the aggregation group in which the plurality of fillers are aggregated may increase. And, when the size of the aggregation group increases, the coefficient of thermal expansion (CTE) of the insulating layer 110 may increase.

As described above, the embodiment allows the insulating layer 110 to have a target level of dielectric constant (Dk), dielectric loss (Df), and coefficient of thermal expansion (CTE) by controlling at least one of the content of the filler 112 and the size of the filler 112 while disposing the filler 112 having a negative coefficient of thermal expansion (negative CTE) in the resin 111 of the insulating layer 110.

In this case, the filler 112 of the embodiment may be disposed to have a negative coefficient of thermal expansion (negative CTE) in a specific direction in the resin 111 of the insulating layer 110. Preferably, the filler 112 may have a negative coefficient of thermal expansion (negative CTE) in the z-axis direction. More preferably, the filler 112 may have a negative coefficient of thermal expansion (negative CTE) in a thickness direction of the insulating layer 110. Accordingly, the embodiment allows to lower the content of the filler 112 by using the filler 112 having a negative coefficient of thermal expansion (negative CTE) in the thickness direction of the insulating layer 110, and accordingly, an increase in the dielectric constant Dk or an increase in the dielectric loss Df of the insulating layer 110 that may occur due to an increase in the content of the filler 112 may be minimized. Furthermore, the embodiment may allow to lower the coefficient of thermal expansion (CTE) in the thickness direction of the insulating layer 110 even with the use of the minimum amount of the filler 112 by using a filler 112 having a coefficient of thermal expansion (CTE) in the thickness direction of the insulating layer 110, and accordingly, warpage characteristics in the thickness direction of the insulating layer 110 and the circuit board including the same may be improved.

Meanwhile, the resin 111 of the embodiment may include only the soluble liquid crystal polymer resin (Soluble LCP) as described above.

Alternatively, the resin 111 of another embodiment may further include a thermosetting resin included in the soluble liquid crystal polymer resin (Soluble LCP).

At this time, when the resin 111 includes only the soluble liquid crystal polymer resin (Soluble LCP), the dielectric constant (Dk) of the insulating layer 110 was at a level of 3.2, and the coefficient of thermal expansion (CTE) was at a level of 99 ppm/K.

On the other hand, when the resin 111 includes a thermosetting resin in the soluble liquid crystal polymer resin (Soluble LCP), the dielectric constant (Dk) and the coefficient of thermal expansion (CTE) of the insulating layer 110 can be further reduced. For example, when the resin 111 includes a soluble liquid crystal polymer resin (Soluble LCP) and a thermosetting resin, the dielectric constant (Dk) of the insulating layer 110 may be 3.0 or less, and the coefficient of thermal expansion (CTE)) may have 95 ppm/K or less.

At this time, the embodiment allows the thermosetting resin of the lowest molecular weight to contain, and through this, it is possible to increase the miscibility of the soluble liquid crystal polymer resin (Soluble LCP) and the thermosetting resin. Furthermore, the thermosetting resin of the embodiment may include an amide bonding group to enable a low coefficient of thermal expansion (CTE) and a dielectric constant (Dk) while increasing solubility in organic solvents.

For example, the thermosetting resin mixed with the soluble liquid crystal polymer resin (Soluble LCP) may include any one of 4-ethynylaniline, Terephthaloyl dichloride, Isophthaloyl dichloride, and 4,4′biphenyldicarbonyl dichloride.

The embodiment allows the resin 111 of the insulating layer 110 to be provided using only the soluble liquid crystal polymer resin (Soluble LCP) or to be provided by including a thermosetting resin mixed with the soluble liquid crystal polymer resin (Soluble LCP). Accordingly, the embodiment can further reduce the dielectric constant (Dk) and the coefficient of thermal expansion (CTE) of the insulating layer 110 by the resin 111 of the insulating layer 110 further including the thermosetting resin in the soluble liquid crystal polymer resin (Soluble LCP),

Meanwhile, referring to FIG. 2, the insulating layer 210 may include a resin 211 and a filler 212 dispersed in the resin 211.

The insulating layer 210 of FIG. 2 is substantially the same as the insulating layer 110 of FIG. 1, and there is a difference in a shape of a filler 212 dispersed in a resin 211 of an insulating layer 210.

For example, the filler 112 in FIG. 1 has a circular or round-like shape.

Alternatively, a filler 212 in FIG. 2 may have a plate shape. For example, the resin 211 of the insulating layer 210 in the embodiment may include only a soluble liquid crystal polymer resin (Soluble LCP) or may have a structure in which a thermosetting resin is mixed with the soluble liquid crystal polymer resin (Soluble LCP).

In addition, a plate-shaped filler 212 may be disposed in the resin 211 of the insulating layer 210 while having a negative coefficient of thermal expansion (CTE) in a thickness direction of the insulating layer 210. At this time, when the filler 212 has a plate-like shape, it is easy to distribute the filler 212 having a negative CTE in the thickness direction of the insulating layer 210 in the resin 211. Accordingly, the coefficient of thermal expansion (CTE) of the insulating layer 210 in the thickness direction can be further reduced.

In this case, as shown in FIG. 2, when the filler 212 is plate-shaped, a size of the filler 212 may mean a length W2 of the plate-shaped filler.

Meanwhile, referring to FIG. 3, the embodiment may provide a flexible copper clad laminate manufactured by laminating a metal layer on the insulating layer 110 of FIG. 1 or the insulating layer 210 of FIG. 2.

For example, the embodiment may provide a flexible copper clad laminate manufactured by laminating a metal layer 120 on a surface of the insulating layer 110 of FIG. 1. However, the embodiment is not limited thereto, and the embodiment may provide a flexible copper clad laminate manufactured by laminating a metal layer on a surface of the insulating layer 210 of FIG. 2.

In this case, the metal layer 120 may be disposed on at least one surface of the insulating layer 110. For example, the metal layer 120 may include a first metal layer 120U disposed on an upper surface of the insulating layer 110. For example, the metal layer 120 may include a second metal layer 1208 disposed under a lower surface of the insulating layer 110. However, the embodiment is not limited thereto, and only one metal layer of the first metal layer 120U and the second metal layer 1208 may be disposed on the insulating layer 110.

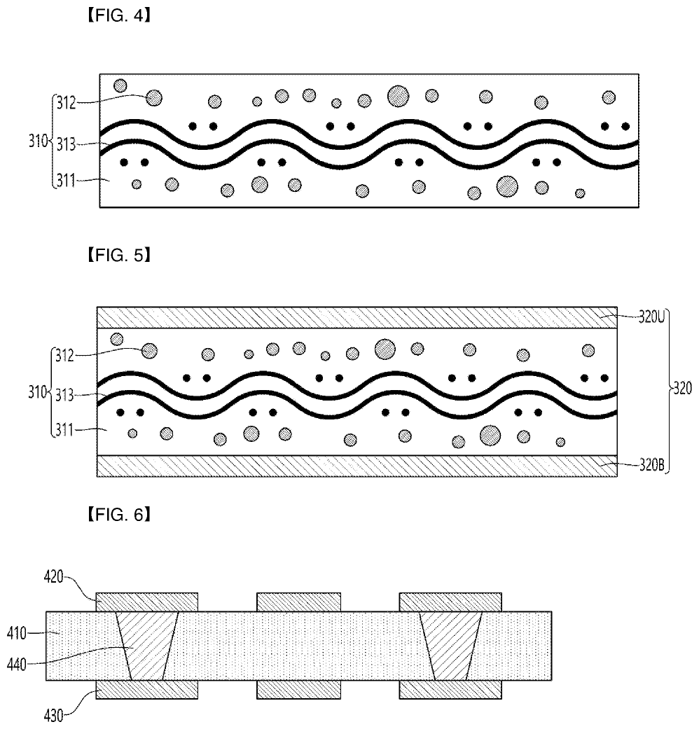

FIG. 4 is a view showing a dielectric layer according to a third embodiment, and FIG. 5 is a view showing a copper clad laminate according to an embodiment.

Referring to FIGS. 4 and 5, the embodiment may provide a dielectric layer or an insulating layer applied to the copper clad laminate. Preferably, FIG. 4 may show a dielectric layer or an insulating layer applied to a copper clad laminate including a glass fiber. For example, FIG. 4 may show a prepreg applied to a copper clad laminate.

Referring to FIGS. 4 and 5, an insulating layer 310 of the embodiment includes a resin 311 and a filler 312 distributed in the resin 311. At this time, the resin 311 and the filler 312 of the insulating layer 310 correspond to the resin or filler shown in FIG. 1 or 2, respectively.

Accordingly, a detailed description of specific characteristics of the resin 311 and the filler 312 included in the insulating layer 310 of the third embodiment will be omitted.

In this case, a glass fiber 312 may be further included in the insulating layer 310 of the embodiment. The glass fiber 312 may be dispersed and disposed together with the filler 312 in the resin 311 of the insulating layer 310, thereby improving physical properties of the insulating layer 310.

In addition, the embodiment may allow the insulating layer 310 to be used as a prepreg applied to a copper clad laminate (CCL) rather than a flexible copper clad laminate by including the glass fiber 312 together with the filler 312 in the resin 311 of the insulating layer 310.

At this time, the insulating layer 310 of the third embodiment may correspond to a basic structure of the first embodiment of FIG. 1 and the second embodiment of FIG. 2. However, the third embodiment may have a difference from the first and second embodiments in that glass fibers 312 are additionally disposed in the insulating layer 310 and in a content of the filler 312 disposed in the insulating layer 310.

The insulating layer 310 may include a glass fiber 312 in the form of a fabric sheet such as a glass fabric woven with glass yarn in the resin 311. However, the glass fiber 312 of the embodiment is not limited thereto. For example, the glass fiber 312 may include a fiber layer in the form of a fabric sheet woven with carbon fiber yarn.

The glass fiber 312 may include carbon fiber, aramid fiber (eg, an aramid-based organic material), nylon, a silica-based inorganic material, or a titania-based inorganic material. The glass fibers 312 may be arranged in a form crossing each other in a planar direction within the resin 311 of the insulating layer 310.

The glass fiber 312 may be provided with a content in a range of 25 wt % to 45 wt % in the insulating layer 310. Preferably, the glass fibers 312 may be provided with a content in a range of 27 wt % to 43 wt % in the insulating layer 310. More preferably, the glass fibers 312 may be provided with a content in a range of 30 wt % to 40 wt % in the insulating layer 310.

When the content of the glass fibers 312 is less than 25 wt %, the coefficient of thermal expansion (CTE) of the insulating layer 310 including the glass fibers 312 increases, and thus, mechanical properties of the insulating layer 310 and the circuit board including the insulating layer 310 may deteriorate. When the content of the glass fibers 312 exceeds 45 wt %, the dielectric constant (Dk) or dielectric loss (Df) of the insulating layer 310 increases, and thus, an insulating layer applicable to high-frequency products may not be provided.

Meanwhile, when the glass fiber 312 is included in the insulating layer 310, an increase in the coefficient of thermal expansion (CTE) caused by the resin 311 of the insulating layer 310 including a soluble liquid crystal polymer resin (Soluble LCP) may be compensated. Accordingly, when the glass fiber 312 is included in the insulating layer 310, a content of the filler 312 in the insulating layer 310 may be reduced.

A content of the filler 312 in the insulating layer 310 may satisfy a range of 2 wt % to 7 wt %. Preferably, a content of the filler 312 in the insulating layer 310 may satisfy a range of 2.2 wt % to 5.5 wt %. More preferably, a content of the filler 312 in the insulating layer 310 may satisfy a range of 2.5 wt % to 5 wt %.

On the other hand, as shown in FIG. 5, the embodiment may provide a copper clad laminate manufactured by laminating a metal layer 320 on the surface of the insulating layer 310 of FIG. 5.

In this case, a metal layer 320 may be disposed on at least one surface of the insulating layer 310. For example, the metal layer 320 may include a first metal layer 320U disposed on an upper surface of the insulating layer 310. For example, the metal layer 320 may include a second metal layer 320B disposed on a lower surface of the insulating layer 310. However, the embodiment is not limited thereto, and only one metal layer of the first metal layer 320U and the second metal layer 320B may be disposed on the insulating layer 310.

As described above, the embodiment provides a resin composition for a semiconductor package. In this case, the resin composition for a semiconductor package includes a resin and a filler dispersed in the resin. In this case, the resin of the embodiment includes a soluble liquid crystal polymer resin (Soluble LCP). Preferably, the resin comprises organo-soluble Liquid Crystalline aromatic polyesters. In addition, the filler disposed in the resin of the embodiment has a negative coefficient of thermal expansion (negative CTE). Preferably, the filler disposed in the resin may have a negative coefficient of thermal expansion (negative CTE) in a thickness direction of an insulating layer.

Accordingly, the embodiment may reduce a dielectric constant (Dk) and a dielectric loss (Df) of the insulating layer by using the soluble liquid crystal polymer resin (Soluble LCP), and may reduce a coefficient of thermal expansion (CTE) of the insulating layer by using a filler having a negative coefficient of thermal expansion (CTE) in the thickness direction.

Accordingly, the embodiment may reduce the dielectric constant (Dk, preferably the dielectric constant at 10 GHz) of the insulating layer to 3.1 or less, 3.0 or less, or 2.9 or less, or 2.7 or less. Further, the embodiment may reduce the coefficient of thermal expansion (CTE) of the insulating layer to less than 100 ppm/K, or 98 ppm/K or less, or 95 ppm/K or less.

Accordingly, the embodiment may minimize the signal loss in a high frequency band, and furthermore, it is possible to provide an insulating layer capable of slimming while improving mechanical properties, electrical properties, and thermal properties, and a circuit board including the same.

FIG. 6 is a view illustrating a circuit board for a semiconductor package according to an embodiment.

Referring to FIG. 6, a circuit board for a semiconductor package includes an insulating layer 410, a first circuit pattern layer 420, a second circuit pattern layer 430 and a through electrode 440.

The insulating layer 410 of the embodiment may be manufactured using any one of the insulating layers shown in FIGS. 1, 2, and 4.

For example, when the insulating layer 410 is the insulating layer of FIG. 1 or 2, the circuit board for a semiconductor package according to the embodiment may be a flexible substrate. For example, when the insulating layer 410 is the insulating layer of FIG. 4, the circuit board for a semiconductor package according to the embodiment may be a rigid substrate.

A circuit pattern layer may be disposed on at least one surface of the insulating layer 410.

Specifically, a first circuit pattern layer 420 may be disposed on an upper surface of the insulating layer 410. In addition, a second circuit pattern layer 430 may be disposed on the lower surface of the insulating layer 410.

The first circuit pattern layer 420 and the second circuit pattern layer 430 are wires that transmit electrical signals, and may be formed of a metal material having high electrical conductivity. To this end, at least one of the first circuit pattern layer 420 and the second circuit pattern layer 430 may be formed of at least one metal material selected from among gold (Au), silver (Ag), platinum (Pt), titanium (Ti), tin (Sn), copper (Cu), and zinc (Zn).

In addition at least one of the first circuit pattern layer 420 and the second circuit pattern layer 430 may be formed of paste or solder paste including at least one metal material selected from among gold (Au), silver (Ag), platinum (Pt), titanium (Ti), tin (Sn), copper (Cu), and zinc (Zn), which are excellent in bonding strength. Preferably, at least one of the first circuit pattern layer 420 and the second circuit pattern layer 430 may be formed of copper (Cu) having high electrical conductivity and a relatively low cost.

A through electrode 440 is disposed in the insulating layer 410. The through electrode 440 may pass through the insulating layer 410 and electrically connect the first circuit pattern layer 420 and the second circuit pattern layer 430.

The through electrode 440 may be formed by filling a through hole penetrating the insulating layer 410 with a conductive material. When the through hole is formed by mechanical processing, methods such as milling, drilling, and routing may be used, and when the through hole is formed by laser processing, a UV or CO2 laser method may be used, and when the through hole is formed by chemical processing, drugs containing aminosilane, ketones, etc. may be used, and the like, thereby the insulating layer 410 may be opened.

On the other hand, the processing by the laser is a cutting method that takes the desired shape to melt and evaporate a part of the material by concentrating optical energy on the surface, it can easily process complex formations by computer programs, and can process composite materials that are difficult to cut by other methods.

In addition, the processing by the laser can have a cutting diameter of at least 0.005 mm, and has a wide advantage in a range of possible thicknesses.

As the laser processing drill, it is preferable to use a YAG (Yttrium Aluminum Garnet) laser, a CO2 laser, or an ultraviolet (UV) laser. The YAG laser is a laser that can process both the copper foil layer and the insulating layer, and the CO2 laser is a laser that can process only the insulating layer.

When the through hole is formed, the through electrode may be formed by filling the inside of the through hole with a conductive material. The metal material forming the through electrode may be any one material selected from copper (Cu), silver (Ag), tin (Sn), gold (Au), nickel (Ni), and palladium (Pd), and the conductive material may be filled using any one or a combination of electroless plating, electrolytic plating, screen printing, sputtering, evaporation, inkjetting and dispensing.

Meanwhile, the embodiment may provide a semiconductor package including at least one chip mounted on a circuit board for a semiconductor package. For example, a package substrate having a structure in which a chip is mounted on a circuit board according to an embodiment may be applied to an electronic device. At this time, the electronic device includes a main board (not shown). The main board may be physically and/or electrically connected to various components. For example, the main board may be connected to a semiconductor package of the embodiment. Various chips may be mounted on the semiconductor package. For example, the semiconductor package may include a memory chip such as a volatile memory (eg, DRAM), a non-volatile memory (eg, ROM), or a flash memory, an application processor chip such as a central processor (eg, CPU), a graphic processor (eg, GPU), a digital signal processor, a cryptographic processor, a microprocessor, or a microcontroller, and a logic chip such as an analog-to-digital converter and an application-specific IC (ASIC).

At this time, the electronic device includes a smart phone, a personal digital assistant, a digital video camera, a digital still camera, a network system, and a computer, a monitor, a tablet, a laptop, a netbook, a television, a video game, a smart watch, an automotive, and the like. However, the embodiment is not limited thereto, and may include any other electronic device that processes data in addition to these.

On the other hand, when the circuit board having the above-described characteristics of the invention is used in an IT device or home appliance such as a smart phone, a server computer, a TV, and the like, functions such as signal transmission or power supply can be stably performed. For example, when the circuit board having the features of the present invention performs a semiconductor package function, it can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other. Furthermore, when the circuit board having the above-described characteristics of the invention is used in a transportation device such as a vehicle, it is possible to transmit a high-current signal required by the vehicle at a high speed, thereby improving the safety of the transportation device. Furthermore, the circuit board and the semiconductor package including the same can be operated normally even in an unexpected situation occurring in various driving environments of the transportation device, thereby safely protecting the driver.

Features, structures, effects, etc. described in the above embodiments are included in at least one embodiment, and it is not necessarily limited to only one embodiment. Furthermore, features, structures, effects, etc. illustrated in each embodiment can be combined or modified for other embodiments by those of ordinary skill in the art to which the embodiments belong. Accordingly, the contents related to such combinations and variations should be interpreted as being included in the scope of the embodiments.

In the above, the embodiment has been mainly described, but this is only an example and does not limit the embodiment, and those of ordinary skill in the art to which the embodiment pertains will appreciate that various modifications and applications not illustrated above are possible without departing from the essential characteristics of the present embodiment. For example, each component specifically shown in the embodiment can be implemented by modification. And the differences related to these modifications and applications should be interpreted as being included in the scope of the embodiments set forth in the appended claims.

What is claimed is:

1. A resin composition for a semiconductor package comprising:
a resin composition comprising a resin and a filler provided in the resin,
wherein the resin includes a soluble liquid crystal polymer resin, and
wherein the filler has a negative coefficient of thermal expansion (negative CTE) and is provided in the soluble liquid crystal polymer resin.

2. The resin composition of claim 1, wherein the filler has a negative coefficient of thermal expansion (negative CTE) in a thickness direction of the resin or a z-axis direction.

3. The resin composition of claim 2, wherein the soluble liquid crystal polymer resin includes an organic soluble liquid crystalline aromatic polyester.

4. The resin composition of claim 2, wherein the filler has a content in a range of 12 wt % to 50 wt %, based on a total weight of the resin composition.

5. The resin composition of claim 1, wherein the filler includes any one of boron nitride (BN), graphene, zirconium tungstate (ZrW2O8), or manganese nitride-based particles.

6. The resin composition of claim 5, wherein the filler has a size in a range of 0.3 μm to 10 μm.

7. The resin composition of claim 6, wherein the filler is a plate-shaped filler, and
wherein the size of the filler is a length of the plate-shaped filler.

8. The resin composition of claim 1, wherein the resin includes the soluble liquid crystal polymer resin and a thermosetting resin, and
wherein the thermosetting resin includes an amide bond group.

9. The resin composition of claim 8, wherein the thermosetting resin includes any one of 4-ethynylaniline, Terephthaloyl dichloride, Isophthaloyl dichloride, and 4,4′biphenyldicarbonyl dichloride.

10. The resin composition of claim 1, further comprising:
a glass fiber provided in the resin.

11. A copper clad laminate comprising:
an insulating layer; and
a metal layer disposed on at least one surface of the insulating layer;
wherein the insulating layer includes a resin and a filler provided in the resin,
wherein the resin includes a soluble liquid crystal polymer resin, and
wherein the filler has a negative coefficient of thermal expansion (negative CTE) and is provided in the soluble liquid crystal polymer resin.

12. The copper clad laminate of claim 11, wherein the filler has a negative coefficient of thermal expansion (negative CTE) in a thickness direction of the resin or a z-axis direction.

13. The copper clad laminate of claim 12, wherein the soluble liquid crystal polymer resin includes an organic soluble liquid crystalline aromatic polyester, and
wherein the filler includes any one of boron nitride (BN), graphene, zirconium tungstate (ZrW2O8), or manganese nitride-based particles.

14. The copper clad laminate of claim 12, wherein the filler has a content in a range of 12 wt % to 50 wt %, based on a total weight of a resin composition of the insulating layer.

15. The copper clad laminate of claim 13, wherein the filler is a plate-shaped filler, and
wherein a length of the plate-shaped filler has a range of 0.3 μm to 10 μm.

16. The copper clad laminate of claim 11, wherein the insulating layer has a dielectric constant (Dk) in a range of 2.5 to 3.1 and a coefficient of thermal expansion (CTE) in a range of 50 ppm/K to 100 ppm/K.

17. The copper clad laminate of claim 11, wherein the insulating layer includes a glass fiber provided in the resin.

18. A circuit board comprising:
an insulating layer; and
a circuit pattern layer disposed on the insulating layer;
wherein the insulating layer includes:
a resin including a soluble liquid crystal polymer resin; and
a filler provided in the resin and having a negative coefficient of thermal expansion (negative CTE), and
wherein the filler has a negative coefficient of thermal expansion (negative CTE) in a thickness direction of the insulating layer.

19. The circuit board of claim 18, wherein the soluble liquid crystal polymer resin includes an organic soluble liquid crystalline aromatic polyester,
wherein the filler is a plate-shaped filler including any one of boron nitride (BN), graphene, zirconium tungstate (ZrW2O8), or manganese nitride-based particles, and
wherein a length of the plate-shaped filler has a range of 0.3 μm to 10 μm.

20. The circuit board of claim 18, wherein the insulating layer has a dielectric constant (Dk) in a range of 2.5 to 3.1 and a coefficient of thermal expansion (CTE) in a range of 50 ppm/K to 100 ppm/K.
